(19) United States
(12) Patent Application Publication
(10) Pub. No.: US 2026/0344259 A1
(43) Pub. Date: Oct. 29, 2026

(54) DISPLAY PANEL AND DISPLAY DEVICE

(71) Applicants: XIAMEN TIANMA DISPLAY TECHNOLOGY CO., LTD., Xiamen (CN); WUHAN TIANMA MICROELECTRONICS CO., LTD., Wuhan (CN)

(72) Inventors: Guofeng ZHANG, Xiamen (CN); Yong YUAN, Xiamen (CN); Lei WANG, Xiamen (CN); You GAO, Xiamen (CN)

(21) Appl. No.: 19/715,181

(22) Filed: Jun. 22, 2026

(30) Foreign Application Priority Data
Mar. 5, 2026 (CN) 202610267251.9

(51) Int. Cl. H10K 59/80; H10K 59/126; H10K 102/00

(52) U.S. Cl. CPC H10K 59/873; H10K 59/126; H10K 2102/351

(57) ABSTRACT

A display panel includes: a substrate, a display layer, an encapsulation layer, a light-filtering layer, a blocking layer, and a first planarization layer. The display layer includes a pixel region and a non-pixel region. The pixel region includes sub-pixels. The light-filtering layer is located on a side of the encapsulation layer away from the substrate. The light-filtering layer includes a light-filtering portion and a light-shielding portion. The light-filtering portion overlaps the pixel region, and the light-shielding portion overlaps the non-pixel region. At least one blocking layer is located on a side of the light-filtering layer away from the substrate, and has an opening. Along the direction perpendicular to the plane of the substrate, the opening overlaps the pixel region, and the blocking layer overlaps the non-pixel region. The first planarization layer is located between the display layer and the blocking layer, and at least covers the display region.

### CROSS-REFERENCE TO RELATED APPLICATIONS

The present application claims priority to Chinese Patent Application No. 202610267251.9, entitled “DISPLAY PANEL AND DISPLAY DEVICE”, filed on Mar. 5, 2026, the content of which is incorporated herein by reference in its entirety.

### TECHNICAL FIELD

The present disclosure relates to the field of display technologies, and in particular, to a display panel and a display device.

### BACKGROUND

The anti-peeping display is widely applied to various application scenarios such as mobile phones, computers and vehicle-mounted displays by virtue of its anti-peeping protection function, effectively satisfying users'display security requirements in public environments and preventing information leakage.

However, current anti-peeping display structures still need to be further optimized, so that they can satisfy higher use requirements.

### SUMMARY

An aspect of the present disclosure provides a display panel. The display panel has a display region and a non-display region that at least partially surrounds the display region. The display panel includes: a substrate, a display layer, an encapsulation layer, a light-filtering layer, at least one blocking layer, and a first planarization layer. The display layer is located on a side of the substrate. The display layer includes a pixel region and a non-pixel region. The pixel region includes sub-pixels. The encapsulation layer is located on a side of the display layer away from the substrate. The light-filtering layer is located on a side of the encapsulation layer away from the substrate. The light-filtering layer includes a light-filtering portion and a light-shielding portion. The light-filtering portion overlaps the pixel region, and the light-shielding portion overlaps the non-pixel region along a direction perpendicular to a plane of the substrate. At least one blocking layer is located on a side of the light-filtering layer away from the substrate, and has an opening. Along the direction perpendicular to the plane of the substrate, the opening overlaps the pixel region, and the at least one blocking layer overlaps the non-pixel region. The first planarization layer is located between the display layer and one of the at least one blocking layer, and at least covers the display region.

A second aspect of the present disclosure provides a display device. The display device includes a display panel. The display panel has a display region and a non-display region that at least partially surrounds the display region. The display panel includes: a substrate, a display layer, an encapsulation layer, a light-filtering layer, at least one blocking layer, and a first planarization layer. The display layer is located on a side of the substrate. The display layer includes a pixel region and a non-pixel region. The pixel region includes sub-pixels. The encapsulation layer is located on a side of the display layer away from the substrate. The light-filtering layer is located on a side of the encapsulation layer away from the substrate. The light-filtering layer includes a light-filtering portion and a light-shielding portion. The light-filtering portion overlaps the pixel region, and the light-shielding portion overlaps the non-pixel region along a direction perpendicular to a plane of the substrate. At least one blocking layer is located on a side of the light-filtering layer away from the substrate, and has an opening. Along the direction perpendicular to the plane of the substrate, the opening overlaps the pixel region, and the at least one blocking layer overlaps the non-pixel region. The first planarization layer is located between the display layer and one of the at least one blocking layer, and at least covers the display region.

### BRIEF DESCRIPTION OF DRAWINGS

In order to more clearly illustrate the embodiments of the present disclosure or the technical solutions in the prior art, the accompanying drawings that need to be used in the description of the embodiments or the prior art are briefly introduced below. The accompanying drawings in the following description are some embodiments of the present disclosure, and for those skilled in the art, other accompanying drawings may be obtained according to these accompanying drawings.

FIG. 1 is a top view of a display panel according to an embodiment of the present disclosure;

FIG. 2 is a cross-sectional view of FIG. 1 taken along A1-A2 according to an embodiment of the present disclosure;

FIG. 3 is a cross-sectional view of FIG. 1 taken along B1-B2 according to an embodiment of the present disclosure;

FIG. 4 is a partial structural schematic diagram of FIG. 2 according to an embodiment of the present disclosure;

FIG. 5 is a cross-sectional view of FIG. 1 taken along A1-A2 according to an embodiment of the present disclosure;

FIG. 6 is a cross-sectional view of FIG. 1 taken along B1-B2 according to an embodiment of the present disclosure;

FIG. 7 is a partial structural schematic diagram of FIG. 5 according to an embodiment of the present disclosure;

FIG. 8 is a schematic diagram of light-emitting comparison according to an embodiment of the present disclosure;

FIG. 9 is a cross-sectional view of FIG. 1 taken along A1-A2 according to an embodiment of the present disclosure;

FIG. 10 is a cross-sectional view of FIG. 1 taken along A1-A2 according to an embodiment of the present disclosure;

FIG. 11 is a schematic diagram of a display panel according to an embodiment of the present disclosure according to an embodiment of the present disclosure;

FIG. 12 is a schematic diagram of a display panel according to an embodiment of the present disclosure;

FIG. 13 is a schematic diagram of a display panel according to an embodiment of the present disclosure;

FIG. 14 is another top view of a display panel according to an embodiment of the present disclosure;

FIG. 15 is a cross-sectional view of FIG. 1 taken along A1-A2 according to an embodiment of the present disclosure;

FIG. 16 is a cross-sectional view of FIG. 1 taken along B1-B2 according to an embodiment of the present disclosure;

FIG. 17 is a schematic diagram of a display panel according to an embodiment of the present disclosure;

FIG. 18 is a schematic diagram of thickness variation of an organic encapsulation layer according to an embodiment of the present disclosure;

FIG. 19 is a schematic diagram of a display panel according to an embodiment of the present disclosure;

FIG. 20 is a schematic diagram of a display panel according to an embodiment of the present disclosure;

FIG. 21 is a schematic diagram of a display panel according to an embodiment of the present disclosure;

FIG. 22 is a schematic diagram of a display panel according to an embodiment of the present disclosure;

FIG. 23 is a schematic diagram of a display panel according to an embodiment of the present disclosure;

FIG. 24 is a schematic diagram of a display panel according to an embodiment of the present disclosure;

FIG. 25 is another top view of a display panel according to an embodiment of the present disclosure;

FIG. 26 is a cross-sectional view of FIG. 25 taken along C1-C2 according to an embodiment of the present disclosure;

FIG. 27 is a schematic diagram of a display panel according to an embodiment of the present disclosure;

FIG. 28 is a schematic diagram of a display panel according to an embodiment of the present disclosure;

FIG. 29 is a cross-sectional view of FIG. 28 taken along D1-D2 according to an embodiment of the present disclosure;

FIG. 30 is a cross-sectional view of FIG. 28 taken along E1-E2 according to an embodiment of the present disclosure;

FIG. 31 is a schematic diagram of a display panel according to an embodiment of the present disclosure;

FIG. 32 is a schematic diagram of a display panel according to an embodiment of the present disclosure; and

FIG. 33 is a schematic diagram of a display device according to an embodiment of the present disclosure.

### DESCRIPTION OF EMBODIMENTS

In order to better understand the technical solutions of the present disclosure, embodiments of the present disclosure will be described in detail below with reference to the drawings.

It should be clear that the described embodiments are merely some of the embodiments of the present disclosure rather than all of the embodiments. Based on the embodiments of the present disclosure, all other embodiments obtained by those of ordinary skill in the art shall fall within the protection scope of the present disclosure.

The terms used in the embodiments of the present disclosure are merely for the purpose of describing specific embodiments, rather than limiting the present disclosure. Singular forms of “a/an”, “said” and “the” used in the embodiments of the present disclosure and the appended claims are also intended to include plural forms, unless the context clearly indicates other meaning otherwise.

It should be understood that the term “and/or” used in the context of the present disclosure is to describe a correlation relation of related objects, indicating that there can be three relations, e.g., A and/or B can indicate only A, both A and B, and only B. Additionally, the symbol “/” in the context generally indicates that the relation between the objects in front and at the back of “/” is an “or” relationship.

The present disclosure provides a display panel. The display panel may be an organic light-emitting diode (OLED) display panel.

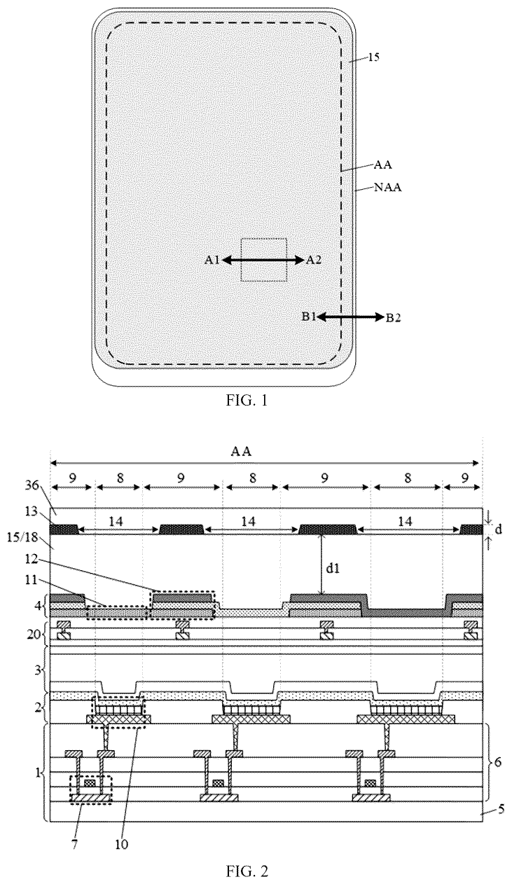

FIG. 1 is a top view of a display panel according to an embodiment of the present disclosure. The display panel includes a display region AA and a non-display region NAA at least partially surrounding the display region AA.

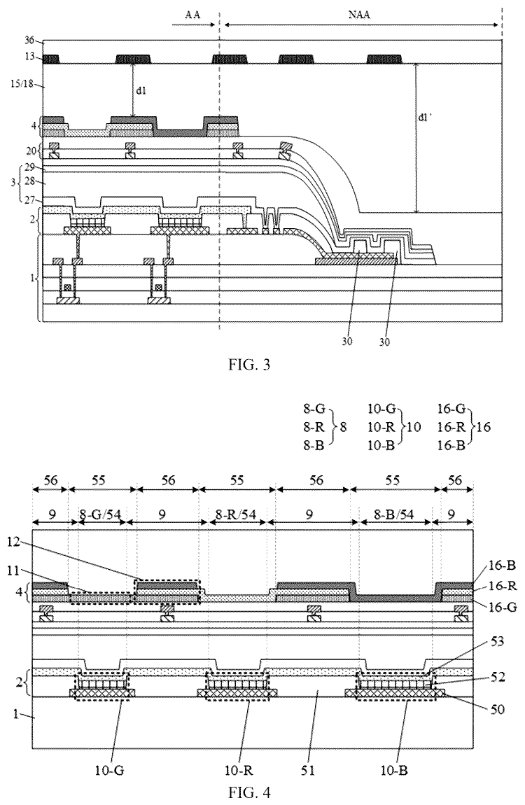

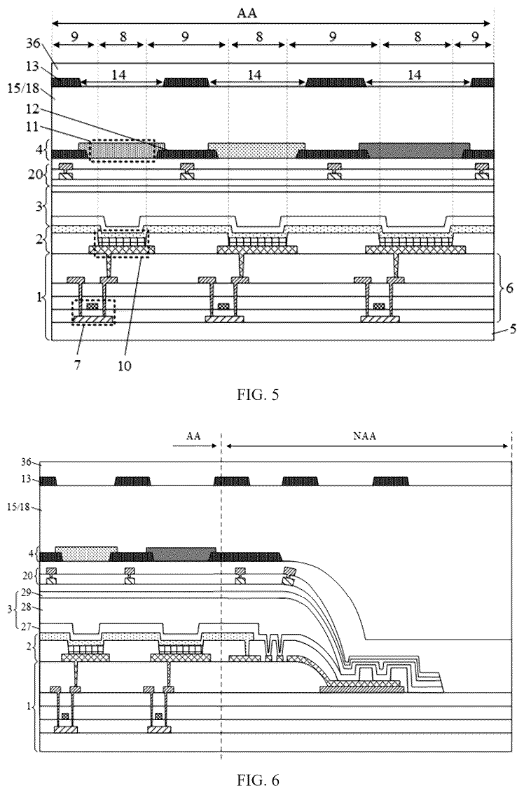

FIG. 2 is a cross-sectional view of the display panel in FIG. 1 taken along A1-A2 according to an embodiment of the present disclosure. FIG. 3 is a cross-sectional view of FIG. 1 taken along B1-B2 according to an embodiment of the present disclosure. FIG. 4 is a partial structural schematic diagram of FIG. 2 according to an embodiment of the present disclosure. FIG. 5 is a cross-sectional view of FIG. 1 taken along A1-A2 according to an embodiment of the present disclosure. FIG. 6 is a cross-sectional view of FIG. 1 taken along B1-B2 according to an embodiment of the present disclosure. FIG. 7 is a partial structural schematic diagram of FIG. 5 according to an embodiment of the present disclosure. As shown in FIG. 1 to FIG. 7, the display panel includes a substrate 1, a display layer 2 located on a side of the substrate 1, an encapsulation layer 3 located on a side of the display layer 2 away from the substrate 1, and a light-filtering layer 4 located on a side of the encapsulation layer 3 away from the substrate 1.

The substrate 1 includes a substrate 5 and a circuit layer 6 located on a side of the substrate 5. The circuit layer 6 includes a pixel circuit 7.

The display layer 2 includes a pixel region 8 and a non-pixel region 9. The pixel region 8 includes sub-pixels 10. In some embodiments, referring to FIG. 4 and FIG. 7, the display layer 2 includes an anode 50, a pixel definition layer 51, a light-emitting layer 52 and a cathode 53. The pixel definition layer 51 has a pixel opening 54. The light-emitting layer 52 is located in the pixel opening 54. The pixel region 8 is defined by the pixel opening 54.

The light-filtering layer 4 is configured for replacing a polarizer to play an anti-reflection role, so as to overcome the problem of an increased thickness of the module caused by the polarizer. The light-filtering layer 4 includes a light-filtering portion 11 and a light-shielding portion 12. Along a direction perpendicular to a plane of the substrate 1, the light-filtering portion 11 overlaps the pixel region 8, and the light-shielding portion 12 overlaps the non-pixel region 9.

In some embodiments, referring to FIG. 4, the light-filtering layer 4 includes a first region 55 and a second region 56. Along the direction perpendicular to the plane of the substrate 1, the first region 55 overlaps the pixel region 8, and the second region 56 overlaps the non-pixel region 9. The light-filtering layer 4 includes color filters 16 of various colors. In the second region 56, the color filters 16 of these multiple colors are stacked to form the light-shielding portion 12. The first region 55 only includes the color filters 16 of one color, a color of the color filters 16 in the first region 55 is the same as a light-emitting color of the corresponding pixel region 8, and this part of the color filter 16 in the first region 55 is the light-filtering portion 11.

In some embodiments, continuing to refer to FIG. 4, the pixel region 8 includes a red pixel region 8-R, a green pixel region 8-G and a blue pixel region 8-B. Correspondingly, the red pixel region 8 includes a red sub-pixel 10-R, the green pixel region 8 includes a green sub-pixel 10-G, and the blue pixel region 8 includes a blue sub-pixel 10-B. The light-filtering layer 4 includes a red color filter 16-R, a green color filter 16-G, and a blue color filter 16-B. The light-filtering layer 4 includes a red color filter 16-R, a green color filter 16-G, and a blue color filter 16-B stacked at a position corresponding to the non-pixel region 9. The light-filtering layer 4 only includes the red color filter 16-R at a position corresponding to the red pixel region 8-R. The light-filtering layer 4 only includes the green color filter 16-G at a position corresponding to the green pixel region 8-G. The light-filtering layer 4 only includes the blue color filter 16-B at a position corresponding to the blue pixel region 8-B.

In some embodiments, referring to FIG. 7, the light-filtering layer 4 includes a first region 55 and a second region 56. Along the direction perpendicular to the plane of the substrate 1, the first region 55 overlaps the pixel region 8, and the second region 56 overlaps the non-pixel region 9. The light-filtering layer 4 includes a black matrix 17 and color filters 16 of various colors. The black matrix 17 is located in the second region 56 and is the light-shielding portion 12. The black matrix 17 has a hollow at a position corresponding to the first region 55. The color filter 16 is at least partially located in the hollow. A color of the color filter 16 in the first region 55 is the same as a light-emitting color of the corresponding pixel region 8, and this part of the color filter 16 in the first region 55 is the light-filtering portion 11.

In some embodiments, continuing to refer to FIG. 7, the light-filtering layer 4 includes a black matrix 17, a red color filter 16-R, a green color filter 16-G, and a blue color filter 16-B. The light-filtering layer 4 includes a black matrix 17 at a position corresponding to the non-pixel region 9. The light-filtering layer 4 includes the red color filter 16-R at a position corresponding to the red pixel region 8-R. The light-filtering layer 4 includes the green color filter 16-G at a position corresponding to the green pixel region 8-G. The light-filtering layer 4 includes the blue color filter 16-B at a position corresponding to the blue pixel region 8-B.

In an embodiment of the present disclosure, thicknesses of the color filters 16 of different colors may be same or different. Additionally, a formation order of the color filters 16 of multiple colors is not limited, for example, in the structure illustrated in FIG. 4, in the second region 56, a stacking order of the color filters 16 of multiple colors is not limited.

In some embodiments, in order to match the current resolution design, that is, to match the spacing design between the current adjacent pixel regions 8, a width of this part of the light-filtering portion 12 between the adjacent pixel regions 8 may be greater than or equal to 3 μm and less than or equal to 30 μm.

Referring to FIG. 2, FIG. 3, FIG. 5 and FIG. 6, the display panel further includes at least one blocking layer 13 located on a side of the light-filtering layer 4 away from the substrate 1. The blocking layer 13 includes a light-shielding material. The blocking layer 13 overlaps the non-pixel region 9 along the direction perpendicular to the plane of the substrate 1. The blocking layer 13 has an opening 14. The opening 14 overlaps the pixel region 8 along the direction perpendicular to the plane of the substrate 1. The light emitted by the sub-pixel 10 further exits through the opening of the blocking layer 13 after exiting through the light-filtering portion 11 of the light-filtering layer 4.

The display panel further includes a first planarization layer 15. The first planarization layer 15 is located between the display layer 2 and the blocking layer 13, and covers the display region AA. The first planarization layer 15 may be an organic layer.

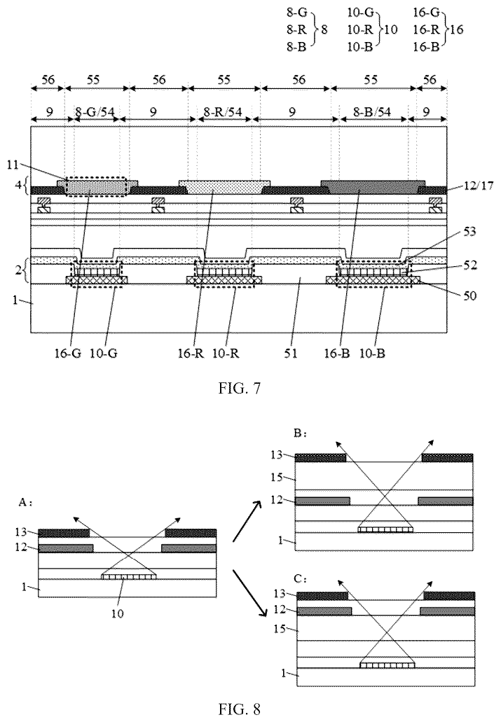

In an embodiment of the present disclosure, the blocking layer 13 is provided on the side of the light-filtering layer 4 away from the substrate 1, and is configured to shield the large-angle light emitted by the sub-pixel 10, such that only the small-angle light is emitted, thereby realizing the anti-peeping function. Further, in an embodiment of the present disclosure, a first planarization layer 15 is provided between the display layer 2 and the blocking layer 13. FIG. 8 is a schematic diagram of light-emitting comparison according to an embodiment of the present disclosure. The sign “A” shown in FIG. 8 schematically shows the light emission when the first planarization layer is not provided, and the signs “B” and “C” in FIG. 5 schematically shows the light emission after the first planarization layer 15 is provided. By comparison, it can be seen that, after providing the first planarization layer 15, an optical distance between the blocking layer 13 and the display layer 2 increases, thereby enabling the blocking layer 13 to shield the light in a larger angle range, enabling the display panel to realize a smaller anti-peeping angle, and thus optimizing the anti-peeping display function.

Additionally, in this technical solution, the first planarization layer 15 and the blocking layer 13 act together to adjust the control of the anti-peeping angle based on the control of the overall thickness of the first planarization layer 15 and the blocking layer 13, thereby reducing the design requirements of the blocking layer 13. For example, under a condition of realizing a same anti-peeping angle, the requirement of the quantity of the blocking layers 13 can be reduced, for example, the anti-peeping at a smaller angle can be realized only by means of one or two blocking layers 13. The quantity of the blocking layers 13 is reduced, the risk of unstable anti-peeping performance caused by a position shift between different blocking layers 13 can be reduced, or the thickness requirement of the blocking layers 13 can also be reduced, thereby realizing the anti-peeping at a smaller angle without excessive thickness of the blocking layers 13, and thus avoiding defective problems such as bottom residual glue and unstable patterns caused by an excessively thick blocking layer 13.

In some embodiments, the quantity of the blocking layer 13 is less than or equal to 2.

In some embodiments, referring to FIG. 2 and FIG. 5, the quantity of the blocking layers 13 is 1, and then the display panel only relies on the single-layer blocking layer 13 to realize anti-peeping, thereby avoiding the problem of anti-peeping angle deviation caused by the position shift between different blocking layers 13.

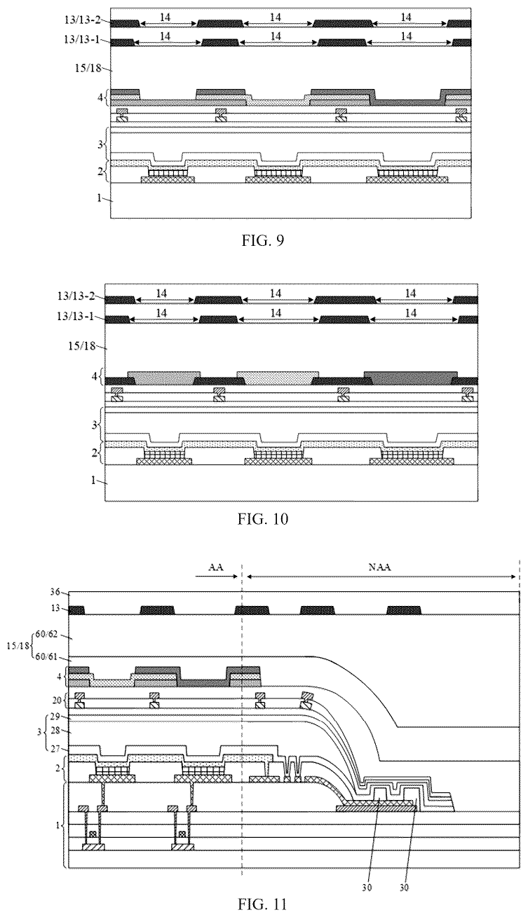

FIG. 9 is a cross-sectional view of FIG. 1 taken along A1-A2 according to an embodiment of the present disclosure. FIG. 10 is a cross-sectional view of FIG. 1 taken along A1-A2 according to an embodiment of the present disclosure. As shown in FIG. 9 and FIG. 10, the display panel includes two blocking layers 13, and along the direction perpendicular to the plane of the substrate 1, there is an interval between the two blocking layers 13. Compared with multiple blocking layers 13, the design of the dual blocking layers can also reduce the risk of unstable anti-peeping performance caused by the position shift of the blocking layer 13. Additionally, the design of the dual blocking layer can also enable the two blocking layers 13 to jointly share thickness requirements, thereby reducing a demand for processing capability of the blocking layer 13, and thus resulting in a more stable pattern of the blocking layer 13.

Further, the two blocking layers 13 include a first blocking layer 13-1 and a second blocking layer 13-2. The second blocking layer 13-2 is located on a side of the first blocking layer 13-1 away from the substrate 1. An area of the opening 14 in the second blocking layer 13-2 is less than the area of the opening 14 overlapping with an opening 14 in the first blocking layer 13-1, thereby further narrowing the light-emitting angle range by the second blocking layer 13-2.

In some embodiments, referring again to FIG. 2, the thickness d of the blocking layer 13 is greater than or equal to 1 μm and less than or equal to 3 μm.

As described above, in some embodiments of the present disclosure, the first planarization layer 15 and the blocking layer 13 act together to adjust the control of the anti-peeping angle based on the control of the overall thickness of the first planarization layer 15 and the blocking layer 13, thereby reducing the thickness requirements of the blocking layer 13. After adding the first planarization layer 15, a smaller anti-peeping angle can be realized when the thickness of the blocking layer 13 ranges from 1 μm to 3 μm. Within this thickness range, the film forming characteristics of the blocking layer 13 are more stable, thereby controlling the anti-peeping angle more accurately.

In some embodiments, in order to match the current resolution design, that is, to match the spacing design between the current adjacent pixel regions 8, a width of this part of the blocking layer 13 between the adjacent pixel regions 8 may be greater than or equal to 3 μm and less than or equal to 30 μm.

In some embodiments, referring again to FIG. 2, FIG. 3, FIG. 5, and FIG. 6, the first planarization layer 15 includes a first planarization sub-layer 18 located between the light-filtering layer 4 and the blocking layer 13.

The light emitted by the sub-pixel 10 further exits through the opening 14 of the blocking layer 13 after exiting through the light-filtering portion 11 of the light-filtering layer 4. The first planarization sub-layer 18 is provided between the light-filtering layer 4 and the blocking layer 13, and the thickness design of the first planarization sub-layer 18 can directly regulate the angle range of light that can further exit through the opening 14 after exiting through the light-filtering portion 11, thereby better adjusting the control of the anti-peeping angle. Additionally, the first planarization sub-layer 18 may further planarize the layer undulations of the light-filtering layer 4, thereby enabling the blocking layer 13 to be more flat.

In some embodiments, referring again to FIG. 2, in the display region AA, a minimum thickness of the first planarization sub-layer 18 is d1, 2 μm≤d1≤30 μm. Then there is a sufficient optical distance between the blocking layer 13 and the light-filtering layer 4, thereby resulting in a design of a small anti-peeping angle. Additionally, d1 is designed to be 30 μm at maximum, which can prevent the first planarization sub-layer 18 from being too thick to affect the thickness of the module while realizing the required anti-peeping angle.

Further, 2 μm≤d1≤15 μm, and this thickness design can enable the display panel to realize an anti-peeping angle less than or equal to 45°, which can satisfy anti-peeping requirements in display fields such as mobile phones and vehicle-mounted displays.

In some embodiments, 12 μm≤d1≤30 μm, this thickness design can enable the display panel to realize an anti-peeping angle less than or equal to 30°, and can be applied to devices and scenarios with higher security requirements.

In some embodiments, referring again to FIG. 2, in the display region AA, the minimum thickness of the first planarization sub-layer 18 is d1, a minimum thickness of the blocking layer 13 is d, where 2≤d1/d≤20.

When d1 and d satisfy the above ratio range, based on the joint action of the first planarization sub-layer 18 and the blocking layer 13, the design of a smaller anti-peeping angle can be realized.

The expression d1/d≥2 means that the thickness of the first planarization sub-layer 18 is at least twice the thickness of the blocking layer 13. When the thickness of the blocking layer 13 is fixed, it can be ensured that the first planarization sub-layer 18 is not too thin, and the first planarization sub-layer 18 has a sufficient thickness to provide stable support for the blocking layer 13, thereby resulting in a sufficient optical distance between the blocking layer 13 and the light-filtering layer 4. When the thickness of the first planarization sub-layer 18 is fixed, an excessively thick blocking layer 13 can be avoided to prevent problems such as unstable patterns caused by the processing capability.

When the thickness of the blocking layer 13 is fixed, an excessively thick first planarization sub-layer 18 can be avoided to prevent an impact on the module thickness. When the thickness of the first planarization sub-layer 18 is fixed, an excessively thin blocking layer 13 can be avoided, enabling the blocking layer 13 to fully play a role in shielding the large-angle light.

In some embodiments, 1 μm≤d≤3 μm, and 12 μm≤d1≤20 μm.

The encapsulation layer 3 includes a first inorganic encapsulation layer 27, an organic encapsulation layer 28, and a second inorganic encapsulation layer 29 stacked along the direction perpendicular to the plane of the substrate 1. The thickness of the organic encapsulation layer 28 is relatively large and is usually formed by an inkjet printing process, and the barrier wall 30 is configured to define a spraying region of the organic encapsulation material, that is, to define a coverage region of the organic encapsulation layer 28. When the non-display region NAA includes multiple rings of barrier walls 30, the region between the barrier wall 30 and the edge of the display panel may refer to the region between an outermost ring of the barrier wall 30 and the edge of the display panel.

As described above, the coverage region of the organic encapsulation layer 28 is located at an inner side of the barrier wall 30. Therefore, the organic encapsulation layer 28 forms a relatively large step difference at the barrier wall 30.

The conventional covering layer above the light-filtering layer 4 is relatively thin and only plays a role of spacing. When the conventional covering layer extends to the non-display region NAA, distinct layer undulations occur due to the step difference. Different from the conventional covering layer, the first planarization sub-layer 18 in this embodiment of the present disclosure is configured to control the anti-peeping angle. The first planarization sub-layer 18 has a relatively large thickness. In the process of forming the first planarization sub-layer 18, the coated or sprayed material is relatively thick, and the material fills a step difference region in the non-display region NAA, thereby enabling a thickness ratio of the first planarization sub-layer 18 in the non-display region NAA to the display region AA ranges from 1.2 to 6. In this way, the first planarization sub-layer 18 may also be configured to improve the layer flatness in the non-display region NAA.

A distance between a surface of the first planarization sub-layer 18 away from the substrate 1 and the substrate 1 in the display region AA may be equal to a distance between a surface of the first planarization sub-layer 18 away from the substrate 1 and the substrate 1 in the non-display region NAA, that is, the surface of the first planarization sub-layer 18 away from the substrate 1 may be a flat surface in the display region AA and the non-display region NAA.

In some embodiments, referring again to FIG. 2, FIG. 3, FIG. 5, and FIG. 6, the first planarization sub-layer 18 is a single-layer film structure.

The single-layer first planarization sub-layer 18 takes into account both regulating the anti-peeping angle and acting as a covering layer. The first planarization sub-layer 18 is a single layer, which has a simple preparation process and a more stable layer structure.

In this structure, the first planarization sub-layer 18 may be formed by a process such as inkjet printing or 3D printing, and both processes may form a single-layer film structure with a stable structure and a large thickness. In some embodiments, the first planarization sub-layer 18 is formed by the inkjet printing process, and the first planarization sub-layer 18 may include materials such as acrylic resin or cycloolefin resin. In some embodiments, the first planarization sub-layer 18 is formed by the 3D printing process, and the first planarization sub-layer 18 may include materials such as transparent resin, transparent PLA, transparent PETG, transparent ABS, and transparent nylon.

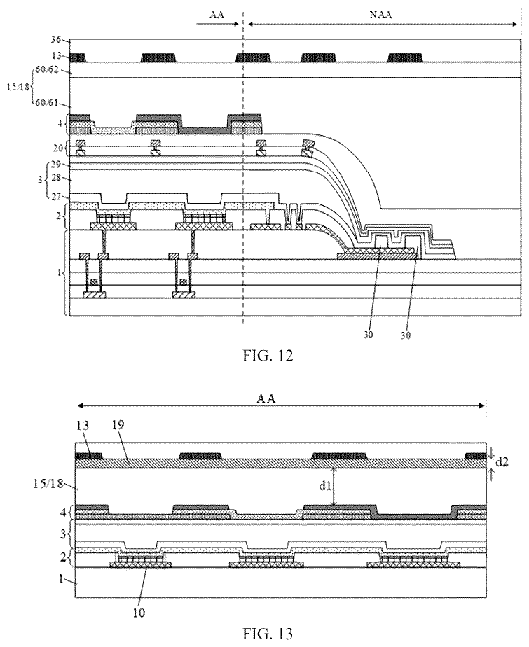

FIG. 11 is a schematic diagram of a display panel according to an embodiment of the present disclosure, and FIG. 12 is a schematic diagram of a display panel according to an embodiment of the present disclosure. As shown in FIG. 11 and FIG. 12, the first planarization sub-layer 18 includes at least two first layers 60 stacked along the direction perpendicular to the plane of the substrate 1.

In this way, the first planarization sub-layer 18 may realize a larger thickness by stacking at least two layers, and the thickness design of the first planarization sub-layer 18 is more flexible. Correspondingly, a regulation design of the anti-peeping angle is also more flexible. In other words, a total stacked thickness of the at least two first layers 60 is configured to satisfy the thickness requirement of the anti-peeping angle for the first planarization sub-layer 18, thereby reducing the thickness requirement of a single first layer 60, and thus reducing the requirement of the processing capability of the first layer 60.

Further, referring again to FIG. 11, the at least two first layers 60 include a first sub-layer 61 and a second sub-layer 62, and the second sub-layer 62 is located on a side of the first sub-layer 61 away from the substrate 1. At least in the display region AA, a thickness of the second sub-layer 62 is greater than a thickness of the first sub-layer 61.

In the above structure, while the first sub-layer 61 and the second sub-layer 62 jointly share the thickness requirement, the second sub-layer 62 is relatively thick, and the second sub-layer 62 is mainly configured to control the anti-peeping angle. The first sub-layer 61 is relatively thin and may be reused as a spacer layer. When the spacer layer extends to the non-display region NAA, relatively distinct layer undulations occurs at a step difference position formed by the organic encapsulation layer 28. In some embodiments, in the display region AA, a minimum thickness of the first sub-layer 61 is about 1.5 μm. In the region between the barrier wall 30 and the edge of the display panel, a minimum thickness of the first sub-layer 61 ranges from 2 μm to 4 μm. The minimum thickness of the first sub-layer 61 in the region between the barrier wall 30 and the edge of the display panel is at most three times the minimum thickness of the first sub-layer 61 in the display region AA.

In some embodiments, referring again to FIG. 12, the at least two first layers 60 include a first sub-layer 61 and a second sub-layer 62, and the second sub-layer 62 is located on a side of the first sub-layer 61 away from the substrate 1. At least in the display region AA, a thickness of the first sub-layer 61 is greater than a thickness of the second sub-layer 62.

In the above structure, while the first sub-layer 61 and the second sub-layer 62 jointly share the thickness requirement, the first sub-layer 61 is relatively thicker, and the first sub-layer 61 is mainly configured to control the anti-peeping angle. The second sub-layer 62 is relatively thin, which can further optimize the flatness of the layer, making the first planarization sub-layer 18 more flat in the display region AA, and thus achieving uniformity of the anti-peeping angle at different positions.

FIG. 13 is a schematic diagram of a display panel according to an embodiment of the present disclosure. As shown in FIG. 13, a first protective layer 19 is further included between the first planarization sub-layer 18 and the blocking layer 13, and the first protective layer 19 is an inorganic layer, for example, including materials such as SiON, SiO, and SiN.

The first protective layer 19 has a compact structure, on one hand, it can block the intrusion of water, oxygen, impurity ions and the like, and on the other hand, it can also prevent the solvent from infiltrating in the forming process of the blocking layer 13, thereby preventing the solvent from reacting with the color filter in the light-filtering layer 4, and thus improving the yield of the panel.

In some embodiments, referring again to FIG. 13, in the display region AA, the minimum thickness of the first planarization sub-layer 18 is d1, and a minimum thickness of the first protective layer 19 is d2, 4≤d1/d2≤200.

Within the above ratio range, not only can the first planarization sub-layer 18 have a sufficient thickness to provide stable support for the blocking layer 13, but also form a sufficient optical distance between the blocking layer 13 and the light-filtering layer 4 to realize a small anti-peeping angle, but also the thickness of the first planarization sub-layer 18 may be limited within a reasonable range, thereby preventing the first planarization sub-layer 18 from being too thick to significantly affect the thickness of the panel while realizing the required anti-peeping angle.

In some embodiments, 50 nm≤d2≤500 nm, and 2 μm≤d1≤10 μm.

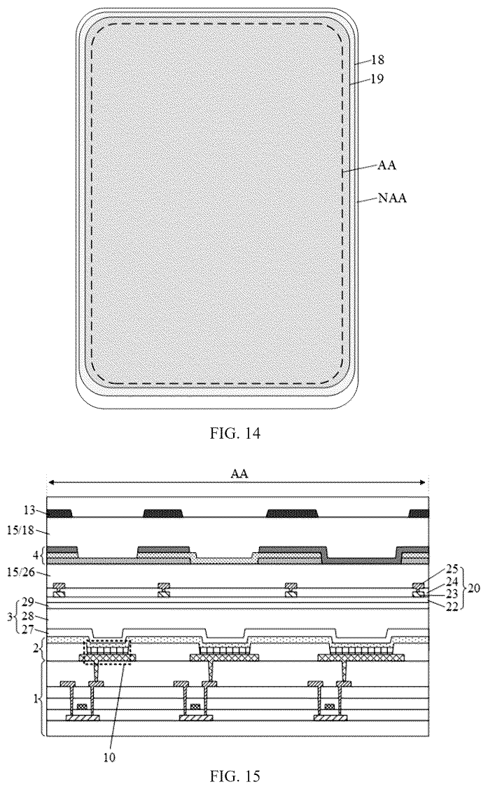

FIG. 14 is another top view of the display panel according to an embodiment of the present disclosure. As shown in FIG. 14, an orthographic projection of the first planarization sub-layer 18 on the plane of the substrate 1 covers an orthographic projection of the first protective layer 19 on the plane of the substrate 1.

When a coverage area of the first planarization sub-layer 18 is greater than a coverage area of the first protective layer 19, compared with the first planarization layer 15, the first protective layer 19 is retracted, thereby relieving stress concentration at the edge of the inorganic layer, reducing the cracking and peeling risks of the layer, and thus enabling the layer to play a protective role better. Additionally, the coverage region of the first planarization sub-layer 18 is larger, and the flatness of the layer at the edge of the panel is better.

In some embodiments, referring again to FIG. 2, the first planarization sub-layer 18 contacts the light-filtering layer 4 on a side adjacent to the substrate 1, and contacts the blocking layer 13 on a side away from the substrate 1.

In the above configuration, only the first planarization sub-layer 18 is spaced between the light-filtering layer 4 and the blocking layer 13. On one hand, the influence of the interface on light transmission can be reduced. On the other hand, the thickness design of the first planarization sub-layer 18 directly determines the optical distance between the blocking layer 13 and the light-filtering layer 4. Based on the thickness control of the first planarization sub-layer 18, the control of the anti-peeping angle can be more finely adjusted. Additionally, the quantity of layers spaced between the light-filtering layer 4 and the blocking layer 13 is relatively small, thereby reducing the process flow and the quantity of masks, and thus saving the cost.

In the above structure, the blocking layer 13 may be formed of a material having poor compatibility with the first planarization sub-layer 18, so as to suppress, at a material level, a solvent of the blocking layer 13 from infiltrating into the first planarization sub-layer 18 during the forming process of the blocking layer 13, thereby avoiding affecting the first planarization sub-layer 18 and the light-filtering layer 4. In some embodiments, the first planarization sub-layer 18 includes an alkyl acrylic resin material, and the blocking layer 13 includes an aromatic acrylic resin material. For example, the blocking layer 13 includes the acrylic resin material containing the fluorene ring.

In some embodiments, the mutual influence between the blocking layer 13 and the first planarization sub-layer 18 may also be reduced by the process selection. For example, in the forming process of the first planarization sub-layer 18, a tetrabutylammonium hydroxide (TMAH) developer with a concentration of 2.38% may be selected for development. In the forming process of the blocking layer 13, a potassium hydroxide (KOH) developer with a concentration of 0.04% may be selected for developing. Such process selection can protect the blocking layer 13 from being affected by the TMAH developer, thereby improving the structural stability of the layer of the blocking layer 13.

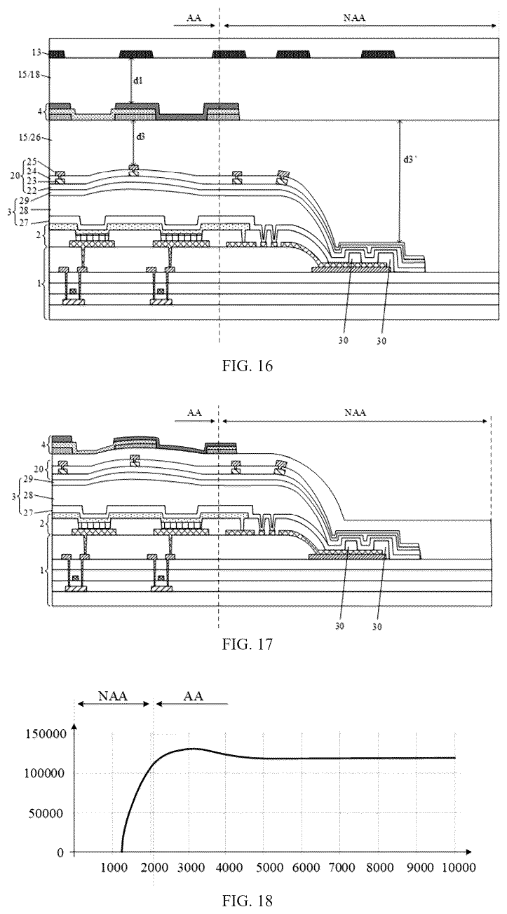

FIG. 15 is a cross-sectional view of FIG. 1 taken along A1-A2 according to an embodiment of the present disclosure, and FIG. 16 is a cross-sectional view of FIG. 1 taken along B1-B2 according to an embodiment of the present disclosure. As shown in FIG. 15 and FIG. 16, the first planarization layer 15 includes a second planarization sub-layer 26 located between the light-filtering layer 4 and the encapsulation layer 3.

The second planarization sub-layer 26 is provided between the light-filtering layer 4 and the encapsulation layer 3. Based on the thickness control of the second planarization sub-layer 26, the control of the optical distance between the blocking layer 13 and the display layer 2 can also be adjusted, thereby realizing the control of the anti-peeping angle.

Additionally, the second planarization sub-layer 26 may further alleviate the frame mura problem.

The encapsulation layer 3 includes a first inorganic encapsulation layer 27, an organic encapsulation layer 28, and a second inorganic encapsulation layer 29 stacked along the direction perpendicular to the plane of the substrate 1. The thicknesses of the first inorganic encapsulation layer 27 and the second inorganic encapsulation layer 29 range from 0.5 μm to 2 μm. The thickness of the organic encapsulation layer 28 ranges from 8 μm to 14 μm. The organic encapsulation layer 28 is usually formed by the inkjet printing process.

FIG. 17 is a schematic diagram of a display panel according to an embodiment of the present disclosure. As shown in FIG. 17, in the forming process of the organic encapsulation layer 28, due to the coffee-ring effect, surface tension and other reasons, the formed organic encapsulation layer 28 is significantly thickened in a region at a position 3 mm to 10 mm from an edge of the display panel, and the position region overlaps the display region AA, so that the organic encapsulation layer 28 is locally thickened in the edge display region, for example, the thickness of the organic encapsulation layer 28 in the edge display region may be 1 μm to 3 μm greater than the thickness of the organic encapsulation layer 28 in the middle display region.

FIG. 18 is a schematic diagram of thickness variation of an organic encapsulation layer according to an embodiment of the present disclosure. An abscissa shown in FIG. 18 corresponds to positions of the display panel, and an ordinate shown in FIG. 18 represents thicknesses of the organic encapsulation layer. As can be seen from FIG. 18, the organic encapsulation layer 28 undergoes a significant thickness variation in a region near the edge of the display panel.

Continuing to refer to FIG. 17, after the thickness of the organic encapsulation layer 28 increases in the edge display region, the light-filtering layer 4 on it is thinned, thereby affecting the light-emitting consistency of the edge display region and the middle display region, resulting in a frame mura phenomenon of the display panel. Such frame mura phenomenon is more obvious in middle-to-low gray scale display.

In an embodiment of the present disclosure, after the second planarization sub-layer 26 is provided between the encapsulation layer 3 and the light-filtering layer 4, referring to FIG. 16, the second planarization sub-layer 26 may planarize thickness undulations of the organic encapsulation layer 28, reduce the influence of thickness variations of the organic encapsulation layer 28 on the thickness of the light-filtering layer 4, and improve the thickness uniformity of the light-filtering layer 4 in the edge display region and the middle display region, thereby effectively alleviating the frame mura problem.

The thickness uniformity of the light-filtering layer 4 in the edge display region and the middle display region may specifically include: a thickness uniformity of the light-filtering portions 11 of a same color in the edge display region and the middle display region, and a thickness uniformity of the light-shielding portions 12 in the edge display region and the middle display region.

In some embodiments, referring again to FIG. 16, in the display region AA, a minimum thickness of the second planarization sub-layer 26 is d3, where 2 μm≤d3≤15 μm.

When d3 ranges from 2 μm to 15 μm, on one hand, the thickness design of the second planarization sub-layer 26 can play a significant role in adjusting and controlling the optical distance between the blocking layer 13 and the display layer 2, thereby realizing effective adjustment and control of the anti-peeping angle; on the other hand, the second planarization sub-layer 26 can also better fill the thickness undulations of the organic encapsulation layer 28, such that the thickness uniformity of the light-filtering layer 4 in the edge display region and the middle display region is superior.

In some embodiments, referring again to FIG. 16, in the display region AA, the minimum thickness in the second planarization sub-layer 26 is d3, the non-display region includes a barrier wall 30. In a region between the barrier wall 30 and an edge of the display panel, a minimum thickness of the second planarization sub-layer 26 is d3′, where 2≤(d3′)/d3≤5.

As described above, the coverage region of the organic encapsulation layer 28 is located at an inner side of the barrier wall 30. Therefore, the organic encapsulation layer 28 forms a relatively large step difference at the barrier wall 30.

A conventional covering layer between the encapsulation layer 3 and the light-filtering layer 4 is relatively thin, and only plays a role of spacing. When the conventional covering layer extends to the non-display region NAA, distinct layer undulations occur at the position of the step difference. Different from the conventional covering layer, in an embodiment of the present disclosure, the second planarization sub-layer 26 is configured to control the anti-peeping angle and to realize planarization to alleviate the frame mura. The second planarization sub-layer 26 has a relatively large thickness. When being coated or sprayed in the forming process of the second planarization sub-layer 26, the material fills the step difference region in the non-display region NAA, thereby enabling the thickness ratio of the second planarization sub-layer 26 in the non-display region NAA to the display region AA ranges from 2 to 5. In this way, the second planarization sub-layer 26 may also be configured to improve the layer flatness in the non-display region NAA.

A distance between a surface of the second planarization sub-layer 26 away from the substrate 1 and the substrate 1 in the display region AA may be equal to a distance between a surface of the second planarization sub-layer 26 away from the substrate 1 and the substrate 1 in the non-display region NAA, that is, the surface of the second planarization sub-layer 26 away from the substrate 1 may be a flat surface in the display region AA and the non-display region NAA.

In some embodiments, 4 μm≤d3′≤32 μm.

In some embodiments, referring again to FIG. 15, and FIG. 16, the second planarization sub-layer 26 is a single-layer film structure.

The single-layer second planarization sub-layer 26 takes into account both regulating the anti-peeping angle and acting as a covering layer. The second planarization sub-layer 26 is a single layer, which has a simple preparation process and a more stable layer structure.

In this structure, the second planarization sub-layer 26 may be formed by inkjet printing or 3D process, and both processes may form a single-layer film structure with a stable structure and a large thickness. In some embodiments, the second planarization sub-layer 26 is formed by the inkjet printing process, and the second planarization sub-layer 26 may include materials such as acrylic resin or cycloolefin resin. In some embodiments, the second planarization sub-layer 26 is formed by the 3D printing process, and the second planarization sub-layer 26 may include materials such as transparent resin, transparent PLA, transparent PETG, transparent ABS, and transparent nylon.

It should be noted that, in the forming process of the display panel, a motherboard including multiple panel regions is generally formed first, and then the motherboard is cut to form multiple independent display panels. When the second planarization sub-layer 26 is formed by the inkjet printing process, a layer covering multiple panel regions may be formed on the motherboard first, and then the layer is cut together when the motherboard is cut to form the independent display panels. Then, even if the layer has a situation of increased edge thickness due to reasons of the forming process, the position of the thickness variation is only at edge positions of the motherboard. When the motherboard is cut into the independent display panels, the part of the layer remaining within the display panel does not have the thickness variation caused by the reasons of the forming process.

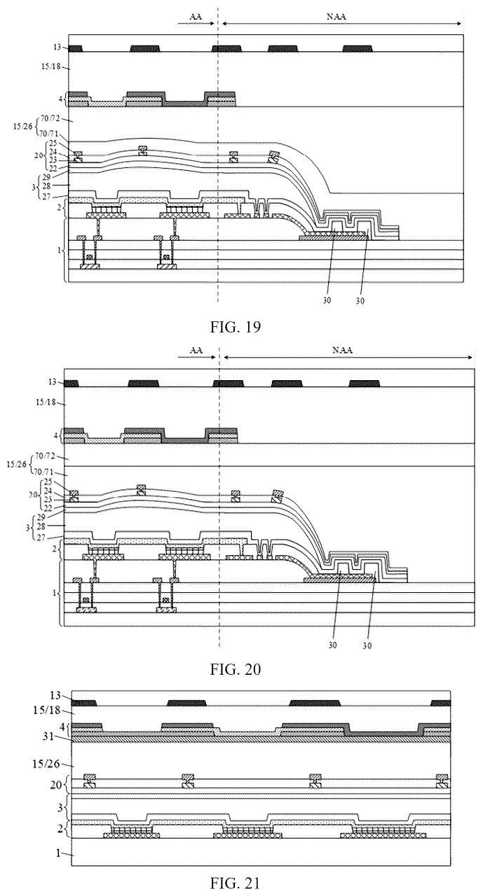

FIG. 19 is a schematic diagram of a display panel according to an embodiment of the present disclosure is a schematic diagram of a display panel according to an embodiment of the present disclosure, and FIG. 20 is a schematic diagram of a display panel according to an embodiment of the present disclosure. As shown in FIG. 19 and FIG. 20, the second planarization sub-layer 26 includes at least two second layers 70 stacked along the direction perpendicular to the plane of the substrate 1.

Then the second planarization sub-layer 26 may realize a larger thickness by stacking at least two layers, resulting in the more flexible thickness design thereof, that is, realizing a smaller anti-peeping angle, and planarizing the anti-peeping angle to a greater extent, and thus alleviating the frame mura phenomenon. In other words, a total stacked thickness of the at least two second layers 70 is configured to satisfy the thickness requirement of the display panel for the second planarization sub-layer 26, thereby reducing the thickness requirement of a single second layer 70, and thus reducing the requirement of the processing capability of the second layer 70.

Further, referring again to FIG. 19, the at least two second layers 70 include a third sub-layer 71 and a fourth sub-layer 72, and the fourth sub-layer 72 is located on a side of the third sub-layer 71 away from the substrate 1. At least in the display region AA, a thickness of the fourth sub-layer 72 is greater than a thickness of the third sub-layer 71.

In the above structure, while the third sub-layer 71 and the fourth sub-layer 72 jointly share the thickness requirement, the fourth sub-layer 72 is relatively thicker, and the fourth sub-layer 72 is mainly configured to control and planarize the anti-peeping angle. The third sub-layer 71 is relatively thin and may be reused as a spacer layer. When the spacer layer extends to the non-display region NAA, relatively distinct layer undulations occurs at a step difference position of the organic encapsulation layer 28. In some embodiments, in the display region AA, a minimum thickness of the third sub-layer 71 is about 1.5 μm. In the region between the barrier wall 30 and the edge of the display panel, a minimum thickness of the third sub-layer 71 ranges from 2 μm to 4 μm. The minimum thickness of the third sub-layer 71 in the region between the barrier wall 30 and the edge of the display panel is at most three times the minimum thickness of the third sub-layer 71 in the display region AA.

In some embodiments, referring again to FIG. 20, the at least two second layers 70 include a third sub-layer 71 and a fourth sub-layer 72, and the fourth sub-layer 72 is located on a side of the third sub-layer 71 away from the substrate 1. At least in the display region AA, a thickness of the third sub-layer 71 is greater than a thickness of the fourth sub-layer 72.

In the above structure, while the third sub-layer 71 and the fourth sub-layer 72 jointly share the thickness requirement, the third sub-layer 71 is relatively thicker, and the third sub-layer 71 is mainly configured to control and planarize the anti-peeping angle. The fourth sub-layer 72 is relatively thin, which can further optimize the flatness of the layer.

In some embodiments, referring again to FIG. 16, the encapsulation layer 3 includes a first inorganic encapsulation layer 27, an organic encapsulation layer 28, and a second inorganic encapsulation layer 29 that are stacked along the direction perpendicular to the plane of the substrate 1.

Along the direction perpendicular to the plane of the substrate 1, the second planarization sub-layer 26 covers the organic encapsulation layer 28, and at least at some same positions, a distance from the second planarization sub-layer 26 to an edge of the display panel is less than a distance from the organic encapsulation layer 28 to the edge of the display panel.

In some embodiments, the organic encapsulation layer 28 covers the display region AA and is further located in the non-display region NAA, the second planarization sub-layer 26 covers the organic encapsulation layer 28, and an edge of the second planarization sub-layer 26 extends beyond an edge of the organic encapsulation layer 28.

For example, at least at some positions, the edge of the second planarization sub-layer 26 is flush with the edge of the display panel. In some embodiments, the non-display region NAA includes an upper frame, a left frame, a lower frame, and a right frame that are sequentially connected. The upper frame and the lower frame are located on opposite sides of the display region AA, the left frame and the right frame are located on opposite sides of the display region AA, and the lower frame may include a bonding region. At the upper frame, the left frame and/or the right frame, the edge of the second planarization sub-layer 26 is flush with the edge of the display panel. At the lower frame, a distance from the second planarization sub-layer 26 to the edge of the display panel is greater than 0, and the second planarization sub-layer 26 exposes the bonding region, so as to avoid affecting the subsequent bonding process.

The second planarization sub-layer 26 covers the organic encapsulation layer 28, thereby better planarizing the thickness undulations of the organic encapsulation layer 28, and thus improving the thickness uniformity of the light-filtering layer 4 in the edge display region and the middle display region.

It should be noted that, when the first planarization layer 15 includes the first planarization sub-layer 18, the first planarization sub-layer 18 may also cover the organic encapsulation layer 28. That is, along the direction perpendicular to the plane of the substrate 1, the first planarization sub-layer 18 covers the organic encapsulation layer 28, and at least at some same positions, a distance from the first planarization sub-layer 18 to an edge of the display panel is less than a distance from the organic encapsulation layer 28 to the edge of the display panel.

In some embodiments, referring again to FIG. 15 and FIG. 16, the display panel further includes a touch layer 20 located between the encapsulation layer 3 and the light-filtering layer 4. The second planarization sub-layer 26 is located between the touch layer 20 and the light-filtering layer 4.

In some embodiments, the touch layer 20 includes a first spacer layer 22, a first electrode layer 23 located on a side of the first spacer layer 22 away from the substrate 1, a second spacer layer 24 located on a side of the first electrode layer 23 away from the substrate 1, and a second electrode layer 25 located on a side of the second spacer layer 24 away from the substrate 1. At least one of the first electrode layer 23 and the second electrode layer 25 includes a touch electrode, and/or at least one of the first electrode layer 23 and the second electrode layer 25 includes a touch trace.

When the display panel includes the touch layer 20, the second planarization sub-layer 26 is located above the touch layer 20, and the film undulations of the touch layer 20 may be planarized to reduce the influence of the film undulations of the touch layer 20 on the thickness uniformity of the light-filtering layer 4.

In some embodiments, the second planarization sub-layer 26 may also be located between the touch layer 20 and the encapsulation layer 3.

FIG. 21 is a schematic diagram of a display panel according to an embodiment of the present disclosure. As shown in FIG. 21, a second protective layer 31 is included between the second planarization sub-layer 26 and the light-filtering layer 4, and the second protective layer 31 is an inorganic layer, for example, including materials such as SiON, SiO, and SiN.

The second protective layer 31 has a compact structure, on one hand, it can block intrusion of water, oxygen, impurity ions and the like, and on the other hand, it can also prevent solvent from infiltrating in the forming process of the light-filtering layer 4, thereby preventing the solvent from reacting the second planarization sub-layer 26 and the touch layer 20, and thus improving the yield of the panel.

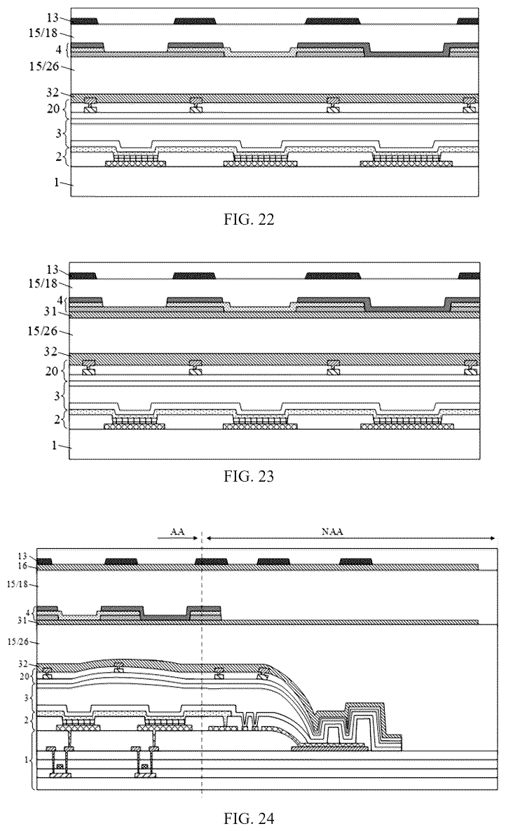

FIG. 22 is a schematic diagram of a display panel according to an embodiment of the present disclosure is a schematic diagram of a display panel according to an embodiment of the present disclosure, and FIG. 23 is a schematic diagram of a display panel according to an embodiment of the present disclosure. As shown in FIG. 22 and FIG. 23, a third protective layer 32 is included between the second planarization sub-layer 26 and the touch layer 20. The third protective layer 32 is an inorganic layer, for example, including materials such as SiON, SiO, and SiN.

The third protective layer 32 has a compact structure, on one hand, it can block intrusion of water, oxygen, impurity ions and the like, and on the other hand, it can also prevent solvent from infiltrating in the forming process of the second planarization sub-layer 26, thereby preventing the solvent from reacting the touch layer 20, and thus improving the yield of the panel.

Further, an edge of the third protective layer 32 is flush with an edge of the second planarization sub-layer 26.

When the second planarization sub-layer 26 is included above the third protective layer 32, the second planarization sub-layer 26 may serve as a mask for the third protective layer 32. In the forming process of the second planarization sub-layer 26 and the third protective layer 32: first, the second planarization sub-layer 26 is patterned, for example, the second planarization sub-layer 26 exposes the bonding region of the lower frame, then the third protective layer 32 is patterned by using the second planarization sub-layer 26 as a mask, then a pattern of the formed third protective layer 32 is consistent with a pattern of the second planarization sub-layer 26, and the edge of the third protective layer 32 is flush with the edge of the second planarization sub-layer 26. In this way, it is unnecessary to separately configure a mask for the third protective layer 32, thereby saving the process cost.

FIG. 24 is a schematic diagram of a display panel according to an embodiment of the present disclosure. As shown in FIG. 24, a second protective layer 31 is included between the second planarization sub-layer 26 and the light-filtering layer 4, and an orthographic projection of the second planarization sub-layer 26 on the plane of the substrate 1 covers an orthographic projection of the second protective layer 31 on the plane of the substrate 1; and/or, a third protective layer 32 is included between the second planarization sub-layer 26 and the touch layer 20, and an orthographic projection of the second planarization sub-layer 26 on the plane of the substrate 1 covers an orthographic projection of the third protective layer 32 on the plane of the substrate 1.

When a coverage area of the second planarization sub-layer 26 is greater than coverage areas of the second protective layer 31 and/or the third protective layer 32. Compared with the second planarization sub-layer 26, the second protective layer 31 and/or the third protective layer 32 are retracted, thereby relieving stress concentration at the edge of the inorganic layer, reducing the cracking and peeling risks of the layer, and thus enabling the layer to play a protective role better.

In some embodiments, referring again to FIG. 16, the first planarization layer 15 includes a first planarization sub-layer 18 and a second planarization sub-layer 26, the first planarization sub-layer 18 is located between the light-filtering layer 4 and the blocking layer 13, and the second planarization sub-layer 26 is located between the light-filtering layer 4 and the encapsulation layer 3.

In the display region AA, the minimum thickness of the first planarization sub-layer 18 is d1, and the minimum thickness of the second planarization sub-layer 26 is d3, where 0.25≤d1/d3≤4.

When the first planarization layer 15 includes the first planarization sub-layer 18 and the second planarization sub-layer 26, the control of the anti-peeping angle may be adjusted based on the overall thickness control of the first planarization sub-layer 18 and the second planarization sub-layer 26. In this way, under a condition that a anti-peeping angle design is fixed, the first planarization sub-layer 18 and the second planarization sub-layer 26 can jointly bear the thickness requirement of the anti-peeping angle on the planarization layer, and the thicknesses of the first planarization sub-layer 18 and the second planarization sub-layer 26 do not need to be too large, thereby reducing the requirement of the processing capability.

When 1≤d1/d3≤4, the thickness of the first planarization sub-layer 18 is greater than or equal to the thickness of the second planarization sub-layer 26. Compared with the second planarization sub-layer 26, the first planarization sub-layer 18 is closer to the blocking layer 13, and the thickness control of the second planarization sub-layer 26 has a more direct regulation on the anti-peeping angle, thereby achieving more precise anti-peeping angle design.

As described above, the second planarization sub-layer 26 is further configured to fill the edge thickness variation of the organic encapsulation layer 28, thereby improving the thickness uniformity of the light-filtering layer 4 in the middle display region and the edge display region. The thicker of the second planarization sub-layer 26 can alleviate the frame mura problem to a greater extent.

In some embodiments, referring again to FIG. 16, the encapsulation layer 3 includes a first inorganic encapsulation layer 27, an organic encapsulation layer 28, and a second inorganic encapsulation layer 29 that are stacked along the direction perpendicular to the plane of the substrate 1.

The first planarization layer 15 includes a first planarization sub-layer 18 and a second planarization sub-layer 26. The first planarization sub-layer 18 is located between the light-filtering layer 4 and the blocking layer 13, and the second planarization sub-layer 26 is located between the light-filtering layer 4 and the encapsulation layer 3.

In the non-display region NAA, a minimum distance between a surface of the first planarization sub-layer 18 adjacent to the substrate 1 (a lower surface of the first planarization sub-layer 18) and the substrate 1 is greater than a maximum distance between a surface of the organic encapsulation layer 28 away from the substrate 1 (an upper surface of the organic encapsulation layer 28) and the substrate 1.

When the first planarization layer 15 includes the first planarization sub-layer 18 and the second planarization sub-layer 26, the second planarization sub-layer 26 is configured to control the anti-peeping angle and realize planarization to alleviate the frame mura, then the second planarization sub-layer 26 has a relatively large thickness. In the forming process of the second planarization sub-layer 26, the material of the second planarization sub-layer 26 will fill the step difference formed by the organic encapsulation layer 28 in the non-display region NAA. Therefore, when the first planarization sub-layer 18 is formed, the material of the first planarization sub-layer 18 may not sink greatly in the non-display region NAA, such that a minimum distance between the lower surface of the first planarization sub-layer 18 and the substrate 1 is greater than a maximum distance between the upper surface of the organic encapsulation layer 28 and the substrate 1 in the non-display region NAA. Then, there is no large thickness variation of the first planarization sub-layer 18 in the coverage region thereof, the thickness uniformity in the entire region is better, the structural characteristics thereof are more stable, thereby allowing for superior adjustment of control of the anti-peeping angle.

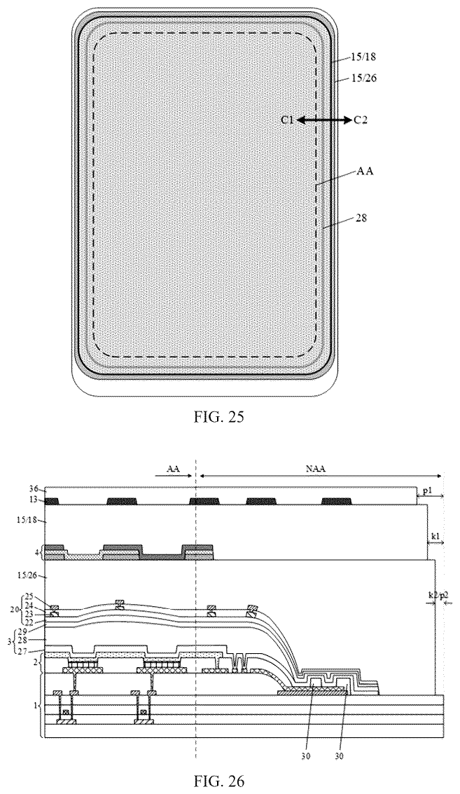

FIG. 25 is another top view of the display panel according to an embodiment of the present disclosure, and FIG. 26 is a cross-sectional view of FIG. 25 taken along C1-C2. As shown in FIG. 25 and FIG. 26, the first planarization layer 15 includes a first planarization sub-layer 18 and a second planarization sub-layer 26. The first planarization sub-layer 18 is located between the light-filtering layer 4 and the blocking layer 13, and the second planarization sub-layer 26 is located between the light-filtering layer 4 and the encapsulation layer 3.

At least at some same positions, a distance between the first planarization sub-layer 18 and an edge of the display panel is k1, and a distance between the second planarization sub-layer 26 and the edge of the display panel is k2, where k1≥k2.

In some embodiments, the non-display region NAA includes an upper frame, a left frame, a lower frame, and a right frame that are sequentially connected. The upper frame and the lower frame are located on opposite sides of the display region AA, the left frame and the right frame are located on opposite sides of the display region AA, and the lower frame may include a bonding region. At the upper frame, the left frame, the right frame and/or the lower frame, the distance between the first planarization sub-layer 18 and the edge of the display panel is greater than the distance between the second planarization sub-layer 26 and the edge of the display panel.

In some embodiments, referring again to FIG. 26, at least at some same positions, k1>k2.

Compared with the second planarization sub-layer 26, the first planarization sub-layer 18 is closer to the blocking layer 13, which has a larger influence on the design of the anti-peeping angle. Therefore, the first planarization sub-layer 18 is designed to be retracted, thereby preventing the first planarization sub-layer 18 from the cutting heat affected region of the panel, that is, preventing the first planarization sub-layer 18 from high-incidence regions of defects and cracks caused by cutting, and reduce the risk of water and oxygen infiltration, thereby effectively improving the adhesion and structural reliability of the first planarization sub-layer 18, and thus making its function more stable.

In some embodiments, referring again to FIG. 16, at least at some same positions, the distance from the first planarization sub-layer 18 to the edge of the display panel may also be equal to the distance from the second planarization sub-layer 26 to the edge of the display panel. For example, at least at some positions, the edge of the first planarization sub-layer 18, the edge of the second planarization sub-layer 26 and the edge of the display panel are flush.

In this structure, the first planarization sub-layer 18 and the second planarization sub-layer 26 may be patterned by using masks with a same pattern, which can save the quantity of masks and reduce the cost of the forming process.

Further, k1−k2≤20 μm, so as to ensure that the first planarization sub-layer 18 has a sufficient coverage area, thereby enabling the first planarization sub-layer 18 to extend beyond the display region AA by a sufficient distance, and thus improving reliability of the first planarization sub-layer 18 in regulating the anti-peeping angle.

In some embodiments, at least at some same positions, the distance between the first planarization sub-layer 18 and the edge of the display panel may also be less than the distance between the second planarization sub-layer 26 and the edge of the display panel, that is, at least at some positions, the first planarization sub-layer 18 extends beyond the second planarization sub-layer 26.

In some embodiments, the at least one first planarization layer 15 includes at least two layers stacked along the direction perpendicular to the plane of the substrate 1. In the display region AA, a total thickness of the at least two layers stacked is greater than or equal to 2 μm and less than or equal to 8 μm.

In some embodiments, the first planarization sub-layer 18 includes at least two layers stacked along the direction perpendicular to the plane of the substrate 1. In the display region AA, a total thickness of the at least two layers stacked is greater than or equal to 2 μm and less than or equal to 8 μm. And/or, the second planarization sub-layer 26 includes at least two layers stacked along the direction perpendicular to the plane of the substrate 1. In the display region AA, a total thickness of the at least two layers stacked is greater than or equal to 2 μm and less than or equal to 8 μm.

In the above structure, the first planarization layer 15 may realize a larger thickness by stacking at least two layers, making its thickness design more flexible, thereby allowing more flexible set of the design of the anti-peeping angle, or realizing planarization to a greater extent, and thus alleviating the frame mura phenomenon.

In some embodiments, the first planarization layer 15 may be formed by a photolithography process, and a stacked layer of the first planarization layer 15 includes materials such as Cardo resin, acrylic-type photoresist, and the like. The photolithography process is limited by conditions of the forming process such as exposure depth, development uniformity, etching control precision and the like, the thickness of the formed layer is limited. In the display region, when the total thickness of the at least two stacked layers ranges from 2 μm to 8 μm, the quantity of the stacked layers is not excessive, which can reduce risks of poor layer bonding force and easy detachment of layers, and can also shorten the cycle of the forming process.

In some embodiments, the first planarization layer 15 includes two layers that are stacked.

In some embodiments, the at least one first planarization layer 15 is a single layer, and a thickness thereof in the display region AA is greater than or equal to 6 μm and less than or equal to 15 μm.

In some embodiments, the first planarization sub-layer 18 is a single layer, and a thickness thereof in the display region AA is greater than or equal to 6 μm and less than or equal to 15 μm. And/or, the second planarization sub-layer 26 is a single layer, and a thickness thereof in the display region AA is greater than or equal to 6 μm and less than or equal to 15 μm.

The first planarization layer 15 is a single layer, which has a simple preparation process and a more stable layer structure.

In some embodiments, the first planarization layer 15 may be formed by a process such as inkjet printing or 3D printing. For example, the first planarization layer 15 is formed by the inkjet printing process, and the first planarization layer 15 may include materials such as acrylic resin or cycloolefin resin. In some embodiments, the first planarization layer 15 is formed by the 3D printing process, and the first planarization layer 15 may include materials such as transparent resin, transparent PLA, transparent PETG, transparent ABS, and transparent nylon.

Both of the above processes can form a single-layer film structure with a stable structure and a larger thickness, and are more suitable for forming a layer with a thickness ranging from 6 μm to 15 μm.

In some embodiments, referring again to FIG. 2, a side of the blocking layer 13 away from the substrate 1 further includes a second planarization layer 36.

The second planarization layer 36 is configured to fill the surface undulations of the blocking layer 13 to achieve surface planarization, which in turn can improve an adhesive effect when a cover plate is bonded.

In some embodiments, in the display region AA, the thickness of the second planarization layer 36 is greater than or equal to 2 μm and less than or equal to 15 μm, so as to cover the step difference of the blocking layer 13.

In some embodiments, the second planarization layer 36 may be formed by a process such as inkjet printing or 3D printing.

In some embodiments, referring again to FIG. 26, at least at some same positions, a distance from the second planarization layer 36 to the edge of the display panel is p1, and a distance from the first planarization layer 15 to the edge of the display panel is p2, where p1≥p2.

When the first planarization layer 15 includes the first planarization sub-layer 18 and the second planarization sub-layer 26, at a corresponding position, a distance between the first planarization sub-layer 18 and the edge of the display panel is k1, a distance between the second planarization sub-layer 26 and the edge of the display panel is k2, and p2 is a minimum value of k2 and k1. For example, as shown in FIG. 26, if k1>k2, then p2 is k2.

In some embodiments, p1>p2, that is, at least at some positions, the coverage area of the first planarization layer 15 is larger, so that the first planarization layer 15 can provide stable support to the second planarization layer 36 at this part of the non-display region NAA.

In some embodiments, p1=p2. For example, at least at some same positions, the distance from the second planarization layer 36 to the edge of the display panel is equal to the distance from the first planarization layer 15 to the edge of the display panel. Then, the second planarization layer 36 and the first planarization layer 15 may be patterned by using masks with the same pattern, which can save the quantity of masks and reduce the cost of the forming process.

Further, p1>p2, p1−p2≥40 μm. Then, the first planarization layer 15 extends by a sufficient distance relative to the second planarization layer 36, so as to provide stable support for the second planarization layer 36.

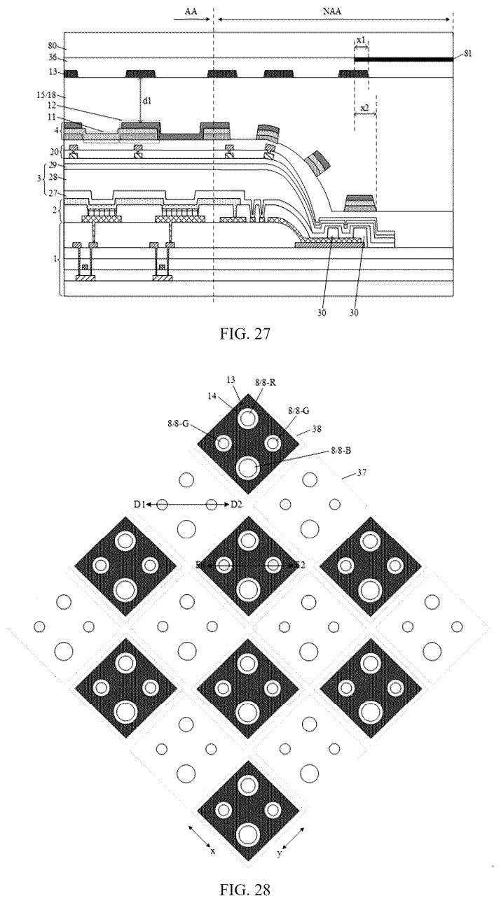

FIG. 27 is a schematic diagram of a display panel according to an embodiment of the present disclosure. As shown in FIG. 27, the display panel further includes a cover plate 80 located on a side of the blocking layer 13 away from the substrate 1. A side of the cover plate 80 adjacent to the substrate 1 includes an ink layer 81. The ink layer 81 is located in the non-display region NAA and may be provided surrounding the display region AA in a circle.

Along the direction perpendicular to the plane of the substrate 1, the blocking layer 13 overlaps the ink layer 81, and/or the light-shielding portion 12 overlaps the ink layer 81.

The ink layer 81, the blocking layer 13 and the light-shielding portion 12 all have light-shielding capability, thereby enabling the blocking layer 13 and/or the light-shielding portion 12 to overlap with the ink layer 81, and thus avoiding edge light leakage caused by gaps between the blocking layer 13, the light-shielding portion 12 and the ink layer 81.

Further, an overlapping width x1 between the blocking layer 13 and the ink layer 81 is greater than or equal to 50 μm, and/or an overlapping width x2 of the light-shielding portion 12 and the ink layer 81 is greater than or equal to 50 μm.

The overlapping width may leave a certain margin for the position shift of the blocking layer 13, the light-shielding portion 12 and the ink layer 81 caused by process precision, reducing risks of edge light leakage to a greater extent.

In some embodiments, a width of the ink layer 81 ranges from 200 μm to 600 μm, and a distance between an inner edge of the ink layer 81 adjacent to the display region AA and an edge of the cover plate 80 is greater than or equal to 200 μm.

When the overlapping width x1 between the blocking layer 13 and the ink layer 81 is greater than or equal to 50 μm, the distance between the blocking layer 13 and the edge of the cover plate 80 is greater than or equal to 150 μm. Further, the distance between the blocking layer 13 and the edge of the cover plate 80 is greater than or equal to 150 μm and less than or equal to 550 μm.

When the overlapping width x2 between the light-shielding portion 12 and the ink layer 81 is greater than or equal to 50 μm, the distance between the light-shielding portion 12 and the edge of the cover plate 80 is greater than or equal to 150 μm. Further, the distance between the light-shielding portion 12 and the edge of the cover plate 80 is greater than or equal to 150 μm and less than or equal to 550 μm. The light-filtering portion 11 in the light-filtering layer 4 then only needs to be located on a side of the barrier wall 30 adjacent to the display region AA.

In some embodiments, the blocking layer 13 may be located only on a periphery of some pixel regions 8. For example, the display panel includes sharing pixels and anti-peeping pixels, and the blocking layer 13 is provided corresponding to the anti-peeping pixels.

Then the display panel includes a sharing mode and an anti-peeping mode. In the sharing mode, at least the sharing pixels emit light. Since the blocking layer 13 is not provided above the sharing pixels, the light emitted by the sharing pixel at a large angle can exit the display panel, such that the display panel has a large viewing angle range. In the anti-peeping mode, the sharing pixels do not emit light, and the anti-peeping pixels emit light. Since the blocking layer 13 is provided above the anti-peeping pixels, the light emitted by the anti-peeping pixels at a large angle is blocked by the blocking layer 13 and cannot exit, and only light at a small angle can exit through the opening 14 of the blocking layer 13, such that the display panel only has a relatively small visible angle range, thereby realizing the anti-peeping.

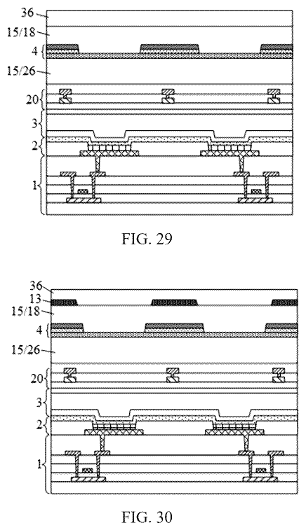

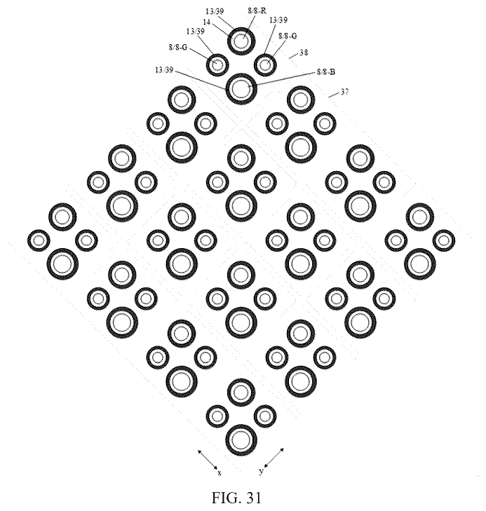

FIG. 28 is a schematic diagram of a display panel according to an embodiment of the present disclosure, FIG. 29 is a cross-sectional view of FIG. 28 taken along D1-D2 according to an embodiment of the present disclosure, and FIG. 30 is a cross-sectional view of FIG. 28 taken along E1-E2 according to an embodiment of the present disclosure. As shown in FIG. 28 to FIG. 30, the display layer 2 includes multiple first light-emitting units 37 and multiple second light-emitting units 38, and the first light-emitting units 37 and the second light-emitting units 38 include multiple pixel regions 8, respectively. The first light-emitting unit 37 may be understood as the sharing pixel and the second light-emitting unit 38 may be understood as the anti-peeping pixel.

In some embodiments, the first light-emitting unit 37 and the second light-emitting unit 38 include a red pixel region 8-R, a green pixel region 8-G, and a blue pixel region 8-B, respectively. The quantity of pixel regions 8 of each color in the first light-emitting unit 37 and the second light-emitting unit 38 is not limited. For example, as shown in FIG. 28, both include one red pixel region 8-R, two green pixel regions 8-G, and one blue pixel region 8-B.

Along the direction perpendicular to the plane of the substrate 1, the blocking layer 13 at least overlaps the non-pixel region 9 in the second light-emitting unit 38, and the opening 14 overlaps the pixel region 8 in the second light-emitting unit 38.

Based on this structure, the display panel includes a sharing mode and an anti-peeping mode.

In the sharing mode, the first light-emitting unit 37 emits light, and the second light-emitting unit 38 may or may not emit light. Since the blocking layer 13 is not provided above the first light-emitting unit 37, the large-angle light emitted by the first light-emitting unit 37 may exit the display panel, so that the display panel has a relatively large viewing angle range.

In the anti-peeping mode, the first light-emitting unit 37 does not emit light, and the second light-emitting unit 38 emits light. Since the blocking layer 13 is provided above the second light-emitting unit 38, the light emitted by the second light-emitting unit 38 at a large angle is blocked by the blocking layer 13 and cannot exit, and only light at a small angle can exit through the opening 14 of the blocking layer 13, such that the display panel only has a relatively small visible angle range, thereby realizing the anti-peeping.

In an embodiment of the present disclosure, the first light-emitting unit 37 and the second light-emitting unit 38 may have various arrangements. For example, as shown in FIG. 28, along a first direction x and a second direction y, the first light-emitting units 37 and the second light-emitting units 38 are both alternately arranged, and the first direction x intersects with the second direction y. In some embodiments, the display layer may include first unit groups and second unit groups alternately arranged along the first direction, where the first unit groups include multiple first light-emitting units 37 arranged along the second direction, and the second unit groups include multiple second light-emitting units 38 arranged along the second direction.

In an embodiment of the present disclosure, the blocking layer 13 overlapping with the single second light-emitting unit 38 may have various structures. For example, as shown in FIG. 28, the blocking layer 13 overlapping with the single second light-emitting unit 38 is an interconnected integrated structure, which includes multiple openings 14. One opening 14 overlaps at least one pixel region 8 in the second light-emitting unit 38. FIG. 31 is a schematic diagram of a display panel according to an embodiment of the present disclosure. As shown in FIG. 31, the blocking layer 13 overlapping with the single second light-emitting unit 38 includes multiple spaced blocking portions 39. Each blocking portion 39 includes at least one opening 14, and one opening 14 overlaps at least one pixel region 8 in the second light-emitting unit 38.

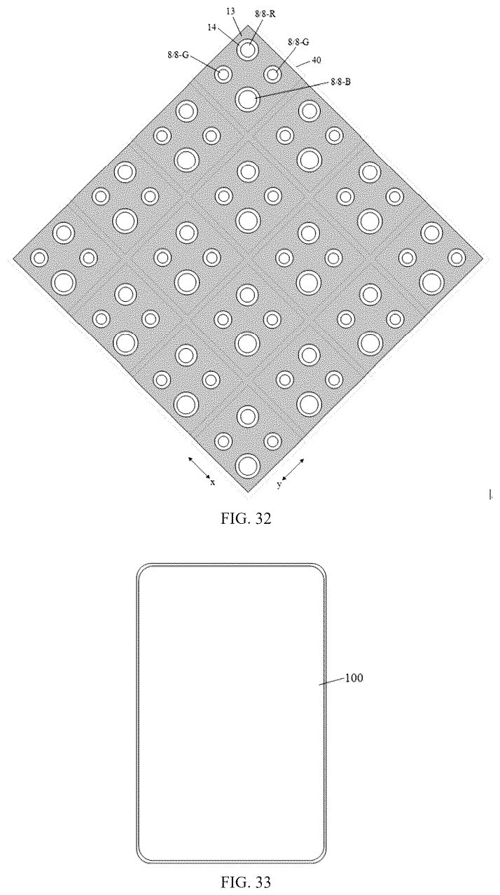

FIG. 32 is a schematic diagram of a display panel according to an embodiment of the present disclosure. As shown in FIG. 32, the display layer 2 includes multiple light-emitting units 40. The light-emitting unit 40 includes multiple pixel regions 8.

For example, the first light-emitting unit 37 and the second light-emitting unit 38 include a red pixel region 8-R, a green pixel region 8-G, and a blue pixel region 8-B, respectively. The quantity of pixel regions 8 of each color in the first light-emitting unit 37 and the second light-emitting unit 38 is not limited. For example, as shown in FIG. 32, both include one red pixel region 8-R, two green pixel regions 8-G, and one blue pixel region 8-B.

Along the direction perpendicular to the plane of the substrate 1, the non-pixel region 9 in each of the light-emitting units 40 overlaps the blocking layer 13.

Such a display panel is a panel structure having a single anti-peeping mode. When the display panel displays an image, after light emitted by each of the light-emitting units 40 exits through the blocking layer 13, only light at a relatively small angle can exit, so that the viewing angle of the display panel is relatively small, thereby achieving the anti-peeping.

Based on the same inventive concept, the present disclosure further provides a display device. FIG. 33 is a structural schematic diagram of a display device according to an embodiment of the present disclosure. As shown in FIG. 33, the display device includes the above display panel 100. The display device shown in FIG. 33 is merely illustrative, and the display device may be any electronic device having a display function such as a mobile phone, a tablet computer, a laptop computer, an e-book, and a television.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various modifications, readjustments, and substitutions without departing from the scope of the present disclosure.

What is claimed is:

1. A display panel, having a display region and a non-display region that at least partially surrounds the display region, and comprising:
a substrate;
a display layer, located on a side of the substrate, and comprising a pixel region and a non-pixel region, wherein the pixel region comprises sub-pixels;
an encapsulation layer, located on a side of the display layer away from the substrate;
a light-filtering layer, located on a side of the encapsulation layer away from the substrate, and comprising a light-filtering portion and a light-shielding portion, wherein along a direction perpendicular to a plane of the substrate, the light-filtering portion overlaps the pixel region, and the light-shielding portion overlaps the non-pixel region;
at least one blocking layer, located on a side of the light-filtering layer away from the substrate, and having an opening, wherein along the direction perpendicular to the plane of the substrate, the opening overlaps the pixel region, and the at least one blocking layer overlaps the non-pixel region; and
a first planarization layer, located between the display layer and one of the at least one blocking layer, and at least covering the display region.

2. The display panel according to claim 1, wherein
a quantity of the at least one blocking layer is less than or equal to 2.

3. The display panel according to claim 1, wherein
the first planarization layer comprises a first planarization sub-layer located between the light-filtering layer and one of the at least one blocking layer.

4. The display panel according to claim 3, wherein
in the display region, a minimum thickness of the first planarization sub-layer is d1, wherein 2 μm≤d1≤30 μm.

5. The display panel according to claim 4, wherein
2 μm≤d1≤15 μm, or 12 μm≤d1≤30 μm.

6. The display panel according to claim 3, wherein
in the display region, a minimum thickness of the first planarization sub-layer is d1, and a minimum thickness of the blocking layer is d, wherein 2≤d1/d≤20.

7. The display panel according to claim 6, wherein
2≤d1/d≤10, or 4≤d1/d≤20.

8. The display panel according to claim 3, wherein
in the display region, a minimum thickness of the first planarization sub-layer is d1, the non-display region comprises a barrier wall, and in a region between the barrier wall and an edge of the display panel, the minimum thickness of the first planarization sub-layer is d1′, wherein 1.2≤d1′/d1≤6.

9. The display panel according to claim 3, wherein
the first planarization sub-layer is a single-layer film structure.

10. The display panel according to claim 3, wherein
the first planarization sub-layer comprises at least two first layers stacked along the direction perpendicular to the plane of the substrate.

11. The display panel according to claim 10, wherein
the at least two first layers comprise a first sub-layer and a second sub-layer, and the second sub-layer is located on a side of the first sub-layer away from the substrate; and
wherein at least in the display region, a thickness of the second sub-layer is greater than a thickness of the first sub-layer.

12. The display panel according to claim 10, wherein
the at least two first layers comprise a first sub-layer and a second sub-layer, and the second sub-layer is located on a side of the first sub-layer away from the substrate; and
wherein at least in the display region, a thickness of the first sub-layer is greater than a thickness of the second sub-layer.

13. The display panel according to claim 3, wherein
a first protective layer is provided between the first planarization sub-layer and the blocking layer.

14. The display panel according to claim 13, wherein
in the display region, a minimum thickness of the first planarization sub-layer is d1, and a minimum thickness of the first protective layer is d2, wherein 4≤d1/d2≤200.

15. The display panel according to claim 13, wherein
an orthographic projection of the first planarization sub-layer on the plane of the substrate covers an orthographic projection of the first protective layer on the plane of the substrate.

16. The display panel according to claim 3, wherein
the first planarization sub-layer contacts the light-filtering layer on a side adjacent to the substrate, and the first planarization sub-layer contacts the blocking layer on a side away from the substrate.

17. The display panel according to claim 1, wherein
the first planarization layer comprises a second planarization sub-layer located between the light-filtering layer and the encapsulation layer.

18. The display panel according to claim 17, wherein
in the display region, a minimum thickness of the second planarization sub-layer is d3, wherein 2 μm≤d3≤15 μm.

19. The display panel according to claim 17, wherein
in the display region, a minimum thickness of the second planarization sub-layer is d3, the non-display region comprises a barrier wall, and in a region between the barrier wall and an edge of the display panel, a minimum thickness of the second planarization sub-layer is d3′, wherein 2≤d3′/d3≤5.

20. A display device, comprising a display panel, wherein the display panel has a display region and a non-display region that at least partially surrounds the display region, and the display panel comprises:
a substrate;
a display layer, located on a side of the substrate, and comprising a pixel region and a non-pixel region, wherein the pixel region comprises sub-pixels;
an encapsulation layer, located on a side of the display layer away from the substrate;
a light-filtering layer, located on a side of the encapsulation layer away from the substrate, and comprising a light-filtering portion and a light-shielding portion, wherein the light-filtering portion overlaps the pixel region, and the light-shielding portion overlaps the non-pixel region along a direction perpendicular to a plane of the substrate;
at least one blocking layer, located on a side of the light-filtering layer away from the substrate, and having an opening, wherein along the direction perpendicular to the plane of the substrate, the opening overlaps the pixel region, and the at least one blocking layer overlaps the non-pixel region; and
a first planarization layer, located between the display layer and one of the at least one blocking layer, and at least covering the display region.
